(19) United States
(12) Patent Application Publication
(10) Pub. No.: US 2026/0226336 A1
(43) Pub. Date: Aug. 6, 2026

(54) A POLYSILOXANE COMPOSITION

(71) Applicant: Wacker Chemie AG, Munich (DE)

(72) Inventors: Junshan YIN, Shanghai (CN); Haigang KANG, Shanghai (CN)

(73) Assignee: Wacker Chemie AG, Munich (DE)

(21) Appl. No.: 19/149,857

(22) PCT Filed: Feb. 23, 2023
(86) PCT No.: PCT/CN2023/077887

§ 371 Date: Jul. 22, 2025

(51) Int. Cl. C09K 5/14; C08G 77/12; C08G 77/20; C08K 9/04; C09C 1/40; C09C 3/08; H05K 1/02

(52) U.S. Cl. CPC C09K 5/14; C08G 77/12; C08G 77/20; C08K 9/04; C09C 1/407; C09C 3/08; H05K 1/0201; C01P 2004/61; C01P 2004/62; C01P 2006/32; C08K 2201/001; C08K 2201/005

(57) ABSTRACT

The present invention relates to a low viscosity silicone composition with high thermal conductivity. It contains vinyl silicone oil, thermally conductive and treatment agent. The composition can be used in the technical field of thermally conductive materials.

### TECHNICAL FIELD

The present invention relates to the technical field of thermally conductive silicone compositions.

### BACKGROUND

KR20210047752A Example 1 disclosed a thermally conductive composition containing silicone resin, alumina trihydrate (ATH) and isopropyl trioleyl titanate. That is, 16% by weight of a silicone resin and 84% by weight of alumina trihydrate (ATH) were mixed. As the alumina trihydrate, those having a particle diameter of 5 m and those having a particle diameter of 50 m were mixed and added in a weight ratio of 40:60. Then 0.5 parts by weight of isopropyl trioleyl titanate was added based on 100 parts by weight of the alumina trihydrate and uniformly mixed with a planetary mixer to obtain a thermally conductive composition for a heat dissipation pad.

KR102218858B1 Example 1 disclosed a thermally conductive gap filler containing oil, thermal conductivity filler, dispersant and antioxidant (mixed weight ratio: 8:108:1:0.3). The oil is synthetic polyalphaolefin oil. There dispersant is a mixture of an organic titanium compound (bis(oleato-O)bis(propan-2-olato)titanium) and oleic acid (mixed weight ratio: organic titanium compound:oleic acid=40-50:40-50).

CN1264932C discloses a method for modifying mica filler with titanate. The diluent acetone is used to prepare a titanate solution. The titanate solution and the filler are mixed for 10-30 minutes under high-speed stirring, and the temperature is controlled to be less than or equal to 90° C.

CN106118136A discloses a method for treating calcium carbonate with titanate and stearic acid. Ex.3 discloses that the calcium carbonate was first treated with titanate for 8 minutes, and then the filler was modified with stearic acid for 15 minutes under 120° C.

### SUMMARY OF INVENTION

30 The object of the present invention is to obtain a treated filler and a treating method that can meet the requirement of lower viscosity thermally conductive compositions.

The present invention also desires to obtain a composition having simultaneously lower viscosity and higher thermal conductivity at high loading levels.

A treated filler (CE) obtained by mixing component (C) thermally conductive filler with component (E-2),
Component (E-2) is a titanate compound represented by the following general formula (2) and/or an oligomer having a degree of polymerization of 2-5,

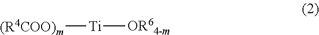

R⁴ is a hydrocarbon group containing 6-30 carbon atoms, and contains at least one carbon-carbon unsaturated group,
preferably, the number of carbon atoms is between 6-24, more preferably between 10-20, more preferably between 16-20; preferably contains 1-3 ethylenic bonds, preferably contains 1-2 ethylenic bonds, more preferably contains 1 ethylenic bond,
R⁴COO— is preferably an oleic acid group;
R⁶ is a hydrocarbon group containing 1-5 carbon atoms, preferably between 1-4 carbon atoms, more preferably methyl, ethyl, ethylene, allyl, propyl, isopropyl, butyl, isobutyl; more preferably propyl, isopropyl;
m is 1 or 2, preferably m is 2;
the mixing conditions are 90-160° C., greater than or equal to 20 min; preferably 100-140° C., 35-70 min; preferably 100-140° C., 40-70 min; preferably 100-130° C., 30-65 min; more preferably 115-125° C., 35-60 min; more preferably 118-122° C., 35-60 min, especially preferred temperature is 95° C., 98° C., 105° C., 110° C., 112° C., 116° C., 128° C., especially preferred time is 32 min, 38 min, 40 min, 42 min, 45 min, 50 min, 52 min, 55 min.

The treated filler (CE) as described above, wherein component (E-2) is used in an amount between 0.05-2.00 wt %, preferably between 0.10-1.00 wt %, more preferably between 0.15-0.60 wt %, More preferably between 0.20-0.45 wt %, calculated on the basis that the amount of the thermally conductive filler in component (C) is 100 wt %.

The treated filler (CE) as described above, wherein component (E-2) is one or more selected from the group consists of di-ethyl di-oleyl titanate, tri-ethyl oleyl titanate, di-n-propyl di-oleyl titanate, tri-n-propyl oleyl titanate, di-isopropyl di-oleyl titanate, tri-isopropyl oleyl titanate, di-butyl di-oleyl titanate, tri-butyl oleyl titanate, preferably di-isopropyl di-oleyl titanate, tri-isopropyl oleyl titanate, more preferably di-isopropyl di-oleyl titanate.

A treating method for the component (C) thermally conductive filler, including mixing the component (C) with component (E-2), wherein the mixing conditions are 90-160° C., greater than or equal to 20 min; preferably 100-140° C., 35-70 min; preferably 100-140° C., 40-70 min; preferably 100-130° C., 30-65 min; more preferably 115-125° C., 35 −60 min; more preferably 118-122° C., 35 −60 min, especially 40 min, 45 min, 50 min, 55 min.

According to the method mentioned above, under the condition of stirring, the component (C) thermally conductive filler is first subjected to nitrogen treatment, and then the component (E-2) is added.

According to the method mentioned above, the nitrogen inertization treatment time is greater than or equal to 5 minutes, preferably 5-60 minutes, more preferably 5-30 minutes, more preferably 5-15 minutes.

According to the method mentioned above, the temperature of nitrogen inertization treatment is room temperature.

According to the method mentioned above, component (E-2) was applied by spraying and/or atomization.

The treated filler (CE) as described above, wherein the amount of solvent used in the mixing process is less than or equal to 1 wt %, preferably less than or equal to 0.5 wt %, more preferably less than or equal to 0.2 wt %, more preferably less than or equal to 0.1 wt %, calculated based on 100 wt % of the thermally conductive filler component (C).

Solvents selected from methanol, ethanol, isopropanol, butanol, acetone, ethyl acetate, formaldehyde, toluene, phthalates, mineral oil, vegetable oil, animal oil, decamethyl-cyclopentasiloxane, octamethyl cyclotetrasiloxane, polydimethylsiloxane with viscosity less than 5 mPa·s.

The present invention provides a composition, which contains:
a component (A), that is an organopolysiloxane, preferably a component (A-1) that is an organopolysiloxane having two or more alkenyl groups per molecule;
optional a component (B) that is an organohydrogenpolysiloxane having two or more hydrogen atoms directly bonded to silicon atoms and is contained in such an amount that the number of moles of hydrogen atoms directly bonded to silicon atoms in the component (B) is 0.1 to 5.0 times the number of moles of alkenyl groups derived from the component (A-1);
the treated filler (CE), wherein the filling amount of the treated filler (CE) is greater than or equal to 0.80, preferably greater than or equal to 0.84, preferably greater than or equal to 0.88, preferably greater than or equal to 0.89, preferably greater than or equal to 0.90;
optional a component (D) that is a platinum group metal-based curing catalyst having a platinum group metal element content of 0.1 to 1,000 ppm relative to the component (A-1) based on mass.

Use of the composition as described above in the field of caulking agent.

Use of the composition as described above in the field of potting.

In electronics, potting is a process of filling a complete electronic assembly with a solid or gelatinous compound for excluding gaseous phenomena, for resistance to shock and vibration, and for the exclusion of water, moisture, or corrosive agents.

For the above-mentioned composition, when the thermal conductivity is greater than 2.5 W/mk, preferably greater than 2.8 W/mk, more greater than 3.0 W/mk, at 25° C. according to DIN53019, when the shear rate is 1 (1/s), the initial viscosity of the composition after mixing is less than or equal to 1000 Pa·s, preferably less than or equal to 500 Pa·s, more preferably less than or equal to 400 Pa·s, more preferably less than or equal to 300 Pa·s.

For the above-mentioned composition, when the thermal conductivity is greater than 2.5 W/mk, preferably greater than 2.8 W/mk, more greater than 3.0 W/mk, at 25° C. according to DIN53019, when the shear rate is 10 (1/s), the initial viscosity of the composition after mixing is less than or equal to 500 Pa·s, preferably less than or equal to 250 Pa·s, more preferably less than or equal to 200 Pa·s, more preferably less than or equal to 150 Pa·s, more preferably less than or equal to 130 Pa·s.

A thermally conductive member comprising the above composition or a cured product thereof.

A heat dissipation structure including the above-mentioned thermally conductive member.

A heat dissipating structure comprising a heat dissipating component or a circuit board on which the heat dissipating component is mounted based on the above composition or a cured product thereof. The above-mentioned heat dissipation structure is an electric/electronic device.

In the present invention, the filling rate=total thermally conductive filler amount/total weight of the composition. Generally, the filling rate which is greater than or equal to 0.88 is considered as the high filling rate.

In above mentioned composition or method, wherein the component (C) thermally conductive filler contains
10-25 wt % (C-1) aluminum hydroxide with an average particle diameter greater than or equal to 0.1 m and less than or equal to 4 m,
   for example (C-1) the average particle diameter is 0.8, 1.0, 1.2, 1.4, 1.6, 1.8, 2.0, 2.2, 2.4, 2.6, 2.8 m, and the content is 14 wt %, 16 wt %, 18 wt %, 20 wt %, 22 wt %, 24 wt %;
18-37 wt % (C-2) aluminum hydroxide with an average particle diameter of 4 μm or more and 20 μm or less,
   for example (C-2) the average particle diameter is 6, 8, 10, 12, 14, 16, 18 m, and the content is 20 wt %, 22 wt %, 24 wt %, 26 wt %, 28 wt %, 30 wt %, 32 wt %, 34 wt %, 36 wt %,
48-65 wt % (C-3) aluminum hydroxide with an average particle diameter greater than or equal to 80 μm and less than or equal to 100 μm,
   for example (C-3) the average particle diameter is 82, 84, 86, 88, 90, 92, 94, 96, 98 μm, and the content is 50 wt %, 52 wt %, 54 wt %, 56 wt %, 58 wt %, 60 wt %, 62 wt %, 64 wt %,
in (C-1), (C-2) and (C-3), the component (C) in the composition is calculated as 100 wt %.

The composition as described above, wherein the total amount of all aluminum hydroxide is greater than 95 wt %, preferably greater than 99 wt %, more preferably greater than 99.9 wt %, and calculated based on the total amount of thermally conductive filler being 100 wt %.

The composition as described above, wherein the total amount of all aluminum hydroxide is greater than 95 wt %, preferably greater than 99 wt %, and more preferably greater than 99.9 wt %, and the total amount of fillers is calculated as 100 wt %.

The composition as described above, wherein the density of the composition is equal to or less than 2.4 g/cm³, preferably equal to or less than 2.2 g/cm³, and more preferably equal to or less than 2.1 g/cm³.

The composition as described above, wherein the thermal conductivity of the composition is greater than or equal to 3.1 W/mK, preferably greater than or equal to 3.2 W/mK.

In the composition as described above, (C-1), (C-2) and (C-3) aluminum hydroxide is all in amorphous form.

In the composition as described above, the amount of the spherical filler is less than 10% by weight, preferably less than 1% by weight, calculated based on the weight of the composition as 100% by weight.

In the composition as described above, the amount of spherical alumina is less than 10% by weight, preferably less than 1% by weight, based on the weight of the composition as 100% by weight.

In the composition as described above, in (C-1), (C-2) and (C-3) aluminum hydroxide, the content of Al(OH)₃ is greater than or equal to 99.1 wt %, preferably greater than or equal to 99.5 wt %.

The composition as described above, wherein (C-1), (C-2) and (C-3) aluminum hydroxide, wherein the content of Na₂O is less than or equal to 0.1 wt %, preferably the total content of water-soluble Na₂O and lattice state Na₂O is less than or equal to 0.1 wt %.

The composition as described above, wherein component (C) containing
10-20 wt % (C-1) Aluminum hydroxide with an average particle diameter greater than or equal to 0.5 μm and less than or equal to 3 μm,
20-35 wt % (C-2) Aluminum hydroxide with an average particle diameter greater than or equal to 7 μm and greater than or equal to 15 μm,
50-60 wt % (C-3) Aluminum hydroxide with an average particle diameter greater than or equal to 85 μm and greater than or equal to 95 μm, in (C-1), (C-2) and (C-3), the component (C) is calculated as 100% by weight.

The composition as described above, wherein the surface-treated aluminum hydroxide is greater than 90 wt %, preferably greater than 95 wt %, more preferably greater than 99 wt %, wherein the component (C) is calculated as 100 wt %.

The composition as described above, wherein the weight ratio of (C-1)/(C-3) is between 0.2 and 0.4, preferably between 0.22 and 0.38, for example 0.25, 0.27, 0.29, 0.31, 0.33, 0.35.

The composition as described above, wherein the weight ratio of (C-2)/(C-3) is between 0.2 and 0.8, preferably between 0.25 and 0.75, for example 0.3, 0.4, 0.5, 0.6, 0.7.

The composition as described above, wherein the ratio of (C-2)/(C-1) average particle diameter is between 8-12, preferably between 9-11, more preferably between 9.5-10.5, for example 9.6, 9.8, 10.0, 10.2, 10.4.

The composition as described above, wherein the ratio of (C-3)/(C-1) average particle diameter is between 70-120, preferably between 75-100, more preferably between 80-99, for example 82, 84, 86, 88, 90, 92, 94, 96, 98.

The composition as described above, wherein the ratio of (C-3)/(C-2) average particle diameter is between 7.0-12.0, preferably between 7.5-10, more preferably between 8.0-9.9, for example 8.2, 8.4, 8.6, 8.8, 9.0, 9.2, 9.4, 9.6, 9.8.

Composition as described above, wherein component (C) contains
20-50 wt % (C-5) alumina with an average particle size greater than or equal to 1 μm and less than or equal to 10 μm,
50-80 wt % (C-6) alumina with an average particle size greater than or equal to 30 μm and less than or equal to 95 μm,
wherein the (C) component is calculated as 100 wt %.

The definition of the average particle diameter refers to the value of the cumulative average particle diameter (D50 median diameter) measured by the particle size analyzer LS 13 320 manufactured by BECKMAN COULTER on a volume basis.

(C-1) the aluminum hydroxide sample is prepared by the solution method. 0.lg (C-1) sample is placed in 10 ml of absolute ethanol, dispersed by ultrasonic (100w) and stirred for 2 minutes, so that the aluminum hydroxide is fully dispersed. Take out 2-3 drops of sample solution and put them into the sample cell of the particle size analyzer.

(C-2) and (C-3) aluminum hydroxide samples (or other thermally conductive fillers with an average particle diameter greater than or equal to 7 m) are prepared by the dry powder method, and an appropriate amount of the sample dried at room temperature is placed into the loading cylinder of the particle size analyzer. Insert the loading cylinder into the detection slot of the device.

In the present invention, the particle size distribution of components in the component (C) is unimodal, or their particle sizes meet unimodal or almost unimodal particle size distributions.

The almost unimodal particle size distributions in the present invention means that in the volume integral map of the measurement sample, there might be two or more peaks, but the volume integral area of the main peak accounts for more than 80% of the entire volume integral area, preferably more than 85%, more preferably more than 90%, more preferably more than 95%.

Spherical fillers, whose outer contour is generally spherical, are filler materials which are obtained from the amorphous fillers treated by chemical and/or physical (including heat treatment) processes.

Spherical alumina is a product obtained after heat treatment of amorphous alumina, and the outer contour is generally spherical.
the component (E-1) could be the treatment agent of component (C), wherein (E-1) is an alkoxysilane compound shown by the following formula (1); and

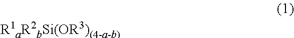

wherein each R¹ independently represents an alkyl group having 1 to 24 carbon atoms, preferably 6 to 24 carbon atoms, more preferably 12 to 18 carbon atoms, each R² independently represents an unsubstituted or substituted hydrocarbon group having 1 to 10 carbon atoms, preferably methyl, ethyl, each R³ independently represents an alkyl group having 1 to 6 carbon atoms, preferably methyl, ethyl,
a represents an integer of 1 to 3, and b represents an integer of 0 to 2, provided that a+b is an integer of 1 to 3.

In the present invention, the weight ratio of (C) component to (E-1) component is between 100-800, preferably between 200-500, and more preferably between 200-400.

As described above, according to the inventive thermal conductive silicone composition, a silicone composition containing specific organopolysiloxane, hydrogenpolysiloxane, and thermally conductive filler is elaborately adjusted and formulated, so that the base material is filled with the thermally conductive filler at high density. This makes it possible to provide a thermal conductive silicone composition which results in a thermal conductive silicone cured product having high thermal conduction, low viscosity and light weight: a thermal conductivity of 3.1 W/m-K or more and a density of 2.4 g/cm³ or less. Such a thermal conductive silicone cured product is useful, particularly for cooling electronic parts through thermal conduction, as a heat conducting material interposed at an interface between a thermal surface of a heat-generating electronic part and a heat dissipating member such as a heat sink or a circuit substrate.

As noted above, there have been demands for the developments of a thermal conductive silicone cured product (thermal conductive resin molded product) having high thermal conduction, low viscosity and light weight, and a thermal conductive silicone composition for forming the cured product.

The present inventors have earnestly studied to achieve the above object and consequently found that a thermal conductive silicone cured product having high thermal conduction, low viscosity and light weight, such as a thermal conductivity of 3.1 W/m-K or more and a density of 2.4 g/cm³ or less, can be obtained by elaborately adjusting and formulating a silicone composition containing specific organopolysiloxane, hydrogenpolysiloxane, and thermally conductive filler to fill the base material with the thermally conductive filler at high density. This finding has led to the completion of the present invention.

Specifically, the present invention is a thermal conductive silicone composition comprising:
Component (A): Organopolysiloxane, preferably Component (A-1): Alkenyl Group-Containing Organopolysiloxane

The component (A) is an organopolysiloxane. The component (A) serves as a main component of the inventive composition. In general, the main chain portion is normally composed of repeated basic diorganosiloxane units, but this molecular structure may partially contain a branched structure, or a cyclic structure. Nevertheless, the main chain is preferably linear diorganopolysiloxane from the viewpoint of physical properties of the cured product, such as mechanical strength. The component (A-1) is an alkenyl group-containing organopolysiloxane in which the number of silicon atom-bonded alkenyl groups is at least two per molecule. The component (A-1) serves as a main component of the inventive composition. In general, the main chain portion is normally composed of repeated basic diorganosiloxane units, but this molecular structure may partially contain a branched structure, or may be a cyclic structure. Nevertheless, the main chain is preferably linear diorganopolysiloxane from the viewpoint of physical properties of the cured product, such as mechanical strength.

Functional groups bonded to a silicon atom include an unsubstituted or substituted monovalent hydrocarbon group. Examples thereof include alkyl groups, such as a methyl group, an ethyl group, a propyl group, an isopropyl group, a butyl group, an isobutyl group, a tert-butyl group, a pentyl group, a neopentyl group, a hexyl group, a heptyl group, an octyl group, a nonyl group, a decyl group, and a dodecyl group; cycloalkyl groups, such as a cyclopentyl group, a cyclohexyl group, and a cycloheptyl group; aryl groups, such as a phenyl group, a tolyl group, a xylyl group, a naphthyl group, and a biphenylyl group; aralkyl groups, such as a benzyl group, a phenylethyl group, a phenylpropyl group, and a methylbenzyl group; and groups obtained from these groups by substituting a part or all of hydrogen atoms bonded to a carbon atom(s) therein with a cyano group, a halogen atom, such as fluorine, chlorine, and bromine, or the like. Examples of such substituted groups include a chloromethyl group, a 2-bromoethyl group, a 3-chloropropyl group, a 3,3,3-trifluoropropyl group, a chlorophenyl group, a fluorophenyl group, a cyanoethyl group, a 3,3,4,4,5,5,6,6,6-nonafluorohexyl group, etc. Typical examples of the functional group include ones having 1 to 10 carbon atoms, and particularly typical examples thereof include ones having 1 to 6 carbon atoms. Preferable examples of the functional group include unsubstituted or substituted alkyl groups having 1 to 3 carbon atoms, such as a methyl group, an ethyl group, a propyl group, a chloromethyl group, a bromoethyl group, a 3,3,3-trifluoropropyl group, and a cyanoethyl group; and unsubstituted or substituted phenyl groups, such as a phenyl group, a chlorophenyl group, and a fluorophenyl group. Additionally, all the functional groups bonded to a silicon atom do not have to be the same.

Furthermore, the alkenyl group normally has about 2 to 8 carbon atoms. Examples thereof include a vinyl group, an allyl group, a propenyl group, an isopropenyl group, a butenyl group, a hexenyl group, a cyclohexenyl group, etc. Among these, lower alkenyl groups, such as a vinyl group and an allyl group, are preferable and a vinyl group is particularly preferable. Note that the number of the alkenyl groups has to be two or more per molecule, and the alkenyl groups are each preferably bonded to only a silicon atom at a terminal of the molecular chain to make the resulting cured product have favorable flexibility.

The component (A) organopolysiloxane has a viscosity at 25° C. in a range of preferably 10 to 100,000 mPa·s, particularly preferably 50 to 50,000 mPa·s, more preferably 50 to 20,000 mPa·s, more preferably 50 to 2,000 mPa·s. The component (A) an organopolysiloxane is preferably a polydimethylsiloxane.

The component (A-1): Alkenyl Group-Containing Organopolysiloxane has a viscosity at 25° C. in a range of preferably 10 to 100,000 mPa·s, particularly preferably 50 to 10,000 mPa·s, more preferably 50 to 1,000 mPa·s, more preferably 50 to 200 mPa·s. When the viscosity is 10 mPa·s or more, the resulting composition has favorable storage stability. Meanwhile, when the viscosity is 100,000 mPa·s or less, the resulting composition has favorable extensibility. The component (A-1) alkenyl group-Containing Organopolysiloxane is preferably a vinyl-terminated polydimethyl-siloxane.

One kind of the organopolysiloxane of the component (A) may be used alone, or two or more kinds thereof having different viscosity or the like may be used in combination.

One kind of the alkenyl group-containing organopolysiloxane of the component (A-1) may be used alone, or two or more kinds thereof having different viscosity or the like may be used in combination.

### Optional Component (B): Organohydrogenpolysiloxane

The component (B) is an organohydrogenpolysiloxane which has at least two, preferably 2 to 100, hydrogen atoms directly bonded to silicon atoms (Si—H groups) per molecule. This component works as a crosslinking agent of the component (A-1). Specifically, a Si H group in the component (B) is added to an alkenyl group in the component (A-1) by a hydrosilylation reaction that is promoted by a platinum group metal-based curing catalyst as the component (D) to be described later, thereby forming a three-dimensional network structure having a crosslinked structure. Note that if the number of Si—H groups per molecule in the component (B) is less than 2, no curing occurs.

The organohydrogenpolysiloxane to be used can be shown by the following average structural formula (4) but is not limited thereto.

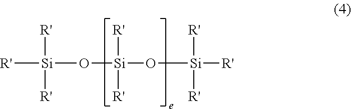

In the formula, each R′ independently represents a hydrogen atom or an unsubstituted or substituted monovalent hydrocarbon group containing no aliphatic unsaturated bond, and at least two R's are hydrogen atoms; e represents an integer of 1 or more.

Examples of the unsubstituted or substituted monovalent hydrocarbon group containing no aliphatic unsaturated bond as R′ other than hydrogen in the formula (4) include alkyl groups, such as a methyl group, an ethyl group, a propyl group, an isopropyl group, a butyl group, an isobutyl group, a tert-butyl group, a pentyl group, a neopentyl group, a hexyl group, a heptyl group, an octyl group, a nonyl group, a decyl group, and a dodecyl group; cycloalkyl groups, such as a cyclopentyl group, a cyclohexyl group, and a cycloheptyl group; aryl groups, such as a phenyl group, a tolyl group, a xylyl group, a naphthyl group, and a biphenylyl group; aralkyl groups, such as a benzyl group, a phenylethyl group, a phenylpropyl group, and a methylbenzyl group; and groups obtained from these groups by substituting a part or all of hydrogen atoms bonded to a carbon atom(s) therein with a cyano group, a halogen atom, such as fluorine, chlorine, and bromine, or the like. Examples of such substituted groups include a chloromethyl group, a 2-bromoethyl group, a 3-chloropropyl group, a 3,3,3-trifluoropropyl group, a chlorophenyl group, a fluorophenyl group, a cyanoethyl group, a 3,3,4,4,5,5,6,6,6-nonafluorohexyl group, etc. Typical examples of the monovalent hydrocarbon group include ones having 1 to 10 carbon atoms, and particularly typical examples thereof include ones having 1 to 6 carbon atoms. Preferable examples of the monovalent hydrocarbon group include unsubstituted or substituted alkyl groups having 1 to 3 carbon atoms, such as a methyl group, an ethyl group, a propyl group, a chloromethyl group, a bromoethyl group, a 3,3,3-trifluoropropyl group, and a cyanoethyl group; and unsubstituted or substituted phenyl groups, such as a phenyl group, a chlorophenyl group, and a fluorophenyl group. Additionally, all R's do not have to be the same.

The amount of the component (B) added is such that, relative to 1 mole of alkenyl groups derived from the component (A-1), the amount of Si—H groups derived from the component (B) is 0.1 to 5.0 moles (i.e., the number of moles of the hydrogen atoms directly bonded to silicon atoms is 0.1 to 5.0 times the number of moles of the alkenyl groups derived from the component (A-1)), preferably 0.3 to 2.0 moles, further preferably 0.5 to 1.0 moles. If the amount of the Si—H groups derived from the component (B) is less than 0.1 moles relative to 1 mole of the alkenyl groups derived from the component (A-1), no curing occurs, or the strength of the cured product is so insufficient that the molded product cannot keep the shape and cannot be handled in some cases. Meanwhile, if the amount exceeds 5.0 moles, the cured product may become inflexible and brittle.

One kind of the organopolysiloxane of the component (B) may be used alone, or two or more kinds thereof having different viscosity or the like may be used in combination.

The composition as described above, wherein component (B) could contains (B-1) and (B-2).

Component (B-1) the organic hydrogen-containing polysiloxane is an organic hydrogen-containing polysiloxane having at least 3, preferably 3-100 hydrogen atoms (Si—H groups) directly bonded to silicon atoms in one molecule, wherein the hydrogen content is between 0.5-4 mmol/g, preferably between 0.8-3 mmol/g, more preferably between 1.1-2.7 mmol/g, and more preferably between 1.5-2.3 mmol/g.

Component (B-2) the organic hydrogen-containing polysiloxane of component is an organic hydrogen-containing polysiloxane having 2 hydrogen atoms (Si—H groups) directly bonded to silicon atoms in one molecule, wherein hydrogen content is between 0.01-1.5 mmol/g, preferably between 0.1-1.2 mmol/g, more preferably between 0.3-1.0 mmol/g, more preferably between 0.4-0.8 mmol/g.

The composition as described above, wherein component (B) contains (B-1) and (B-2), and the amount of component (B-1) is between 0.5-3 wt %, preferably 1.5-2.5 wt %, based on the component (A-1) calculated as 100 wt %.

The composition as described above, wherein component (B) contains (B-1) and (B-2), and the amount of component (B-2) is between 10-50 wt %, preferably between 20-40 wt %, based on the component (A-1) calculated as 100 wt %.

Component (C): Thermally conductive Filler Thermally conductive fillers generally do not contain fumed silica or precipitated silica.

In the composition of the present invention, the content of fumed silica and/or precipitated silica is less than 1 wt % preferably less than 0.1 wt %, calculated based on the total composition of 100 wt %.

The thermally conductive filler is not particularly limited. It is possible to use materials generally considered to be a thermally conductive filler, including non-magnetic metal, such as copper or aluminum; metal oxide, such as alumina, silica, magnesia, colcothar, beryllia, titania, or zirconia; metal nitride, such as aluminum nitride, silicon nitride, or boron nitride; metal hydroxide, such as aluminum hydroxide, magnesium hydroxide; artificial diamond, silicon carbide, etc. Additionally, the particle size of 0.1 to 200 μm may be employed. One or two or more kinds thereof may be used as a composite.

Preferably component (C) thermally conductive filler is a metal oxide and/or metal hydroxide.

The component (C) has to be blended in an amount of 800 to 4,000 parts by mass, preferably 900 to 2,000 parts by mass, more preferably 900 to 1,500 parts by mass, relative to 100 parts by mass of the component (A). If this blend amount is less than 800 parts by mass, the resulting composition has poor thermal conductivity. If the blend amount exceeds 2,000 parts by mass, the kneading operability is impaired, and the cured product becomes significantly brittle.

Optional Component (D): Platinum Group Metal-Based Curing Catalyst The component (D) is a platinum group metal-based curing catalyst and is not particularly limited, as long as the catalyst promotes an addition reaction of an alkenyl group derived from the component (A-1) and a Si—H group derived from the component (B). Examples of the catalyst include well-known catalysts used in hydrosilylation reaction. Specific examples include: platinum group metal simple substances, such as platinum (including platinum black), rhodium, and palladium; platinum chloride, chloroplatinic acid, and chloroplatinate, such as H₂PtCl₄·nH₂O, H₂PtCl₆·nH₂O, NaHPtCl₆·nH₂O, KHPtCl₆·nH₂O, Na₂PtCl₆·nH₂O, K₂PtCl₄·nH₂O, PtCl₄·nH₂O, PtCl₂, and Na₂HPtCl₄·nH₂O (here, in the formulae, n is an integer of 0 to 6, preferably 0 or 6); alcohol-modified chloroplatinic acid (see specification of U.S. Pat. No. 3,220,972); complexes of chloroplatinic acid with olefin (see U.S. Pat. No. 3,159,601 specification, U.S. Pat. No. 3,159,662 specification, and U.S. Pat. No. 3,775,452 specification); ones obtained by supporting a platinum group metal, such as platinum black and palladium, on a support, such as alumina, silica, or carbon; a rhodium-olefin complex, chlorotris(triphenylphosphine)rhodium (Wilkinson catalyst); complexes of platinum chloride, chloroplatinic acid, or chloroplatinate with a vinyl group-containing siloxane, particularly a vinyl group-no more containing cyclic siloxane; etc.

The component (D) is used in such an amount that the platinum group metal element content is 0.1 to 1,000 ppm relative to the component (A-1) based on mass. If the content is less than 0.1 ppm, sufficient catalyst activity is not obtained. If the content exceeds 1,000 ppm, the cost is merely increased without enhancing the effect of promoting the addition reaction, and the catalyst remaining in the cured product may decrease the insulating property, too.

Component (E-1): an alkoxysilane compound shown by the following formula (1),

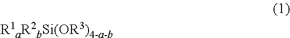

“where each R¹ independently represents an alkyl group having 1 to 24 carbon atoms, preferably 6 to 24 carbon atoms, more preferably 12 to 18 carbon atoms, each R² independently represents an unsubstituted or substituted hydrocarbon group having 1 to 10 carbon atoms, preferably methyl, ethyl, each R³ independently represents an alkyl group having 1 to 6 carbon atoms, a represents an integer of 1 to 3, and b represents an integer of 0 to 2, provided that a+b is an integer of 1 to 3.

Examples of the alkyl group represented by R¹ in the formula (1) include a hexyl group, an octyl group, a nonyl group, a decyl group, a dodecyl group, a tetradecyl group, etc. When the number of carbon atoms in the alkyl group represented by R¹ satisfies the range of 6 to 15, the wettability of the component (A) is sufficiently enhanced, resulting in excellent handleability. Moreover, the composition has favorable low temperature characteristics.

Examples of the unsubstituted or substituted hydrocarbon group represented by R² include alkyl groups, such as a methyl group, an ethyl group, a vinyl group, a propyl group, an isopropyl group, a butyl group, an isobutyl group, a tert-butyl group, a pentyl group, a neopentyl group, a hexyl group, a heptyl group, an octyl group, a nonyl group, a decyl group, and a dodecyl group; cycloalkyl groups, such as a cyclopentyl group, a cyclohexyl group, and a cycloheptyl group; aryl groups, such as a phenyl group, a tolyl group, a xylyl group, a naphthyl group, and a biphenylyl group; aralkyl groups, such as a benzyl group, a phenylethyl group, a phenylpropyl group, and a methylbenzyl group; and groups obtained from these groups by substituting a part or all of hydrogen atoms bonded to a carbon atom(s) therein with a cyano group, a halogen atom, such as fluorine, chlorine, and bromine, or the like. Examples of such substituted groups include a chloromethyl group, a 2-bromoethyl group, a 3-chloropropyl group, a 3,3,3-trifluoropropyl group, a chlorophenyl group, a fluorophenyl group, a cyanoethyl group, a 3,3,4,4,5,5,6,6,6-nonafluorohexyl group, etc. Typical examples of the monovalent hydrocarbon group include ones having 1 to 10 carbon atoms, and particularly typical examples thereof include ones having 1 to 6 carbon atoms. Preferable examples of the monovalent hydrocarbon group include unsubstituted or substituted alkyl groups having 1 to 3 carbon atoms, such as a methyl group, an ethyl group, a propyl group, a chloromethyl group, a bromoethyl group, a 3,3,3-trifluoropropyl group, and a cyanoethyl group; and unsubstituted or substituted phenyl groups, such as a phenyl group, a chlorophenyl group, and a fluorophenyl group.

Examples of R³ include a methyl group, an ethyl group, a propyl group, a butyl group, a hexyl group, etc. Further, a and b are not particularly limited, as long as a is an integer of 1 to 3, b is an integer of 0 to 2, and a+b is an integer of 1 to 3. Preferably, a is 1 and b is 0.

The component (E-1) is preferably an alkoxysilane containing a C6-18 long-chain alkyl group; more preferably a trialkoxysilane containing a C6-18 long-chain alkyl group; more preferably hexadecyltrimethoxy silane, hexadecyltriethoxy silane, tetradecyltrimethoxy silane, tetradecyl-triethoxy silane, dodecyltrimethoxysilane, dodecyltriethoxysilane.

Compared to 100 wt % of component (C), the amount of component (E-1) is less than 1 wt %, more preferably less than 0.5 wt %, more preferably less than 0.1 wt %.

### Component (F): Property-Imparting Agent

As a component (F), it is possible to add an organopolysiloxane having a viscosity at 25° C. of 10 to 100,000 mPa·s and shown by the following formula (3),

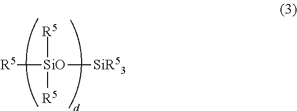

where each R⁵ independently represents a monovalent hydrocarbon group having 1 to 10 carbon atoms and no aliphatic unsaturated bond; and d represents an integer of 5 to 2,000.

The component (F) is used as appropriate in order to impart properties as a viscosity adjuster, plasticizer, and so forth for the thermal conductive silicone composition, but is not limited thereto.

One kind of these may be alone, or two or more kinds thereof may be used in combination.

Each R⁵ independently represents an unsubstituted or substituted monovalent hydrocarbon group having 1 to 10 carbon atoms. Examples of R⁵ include alkyl groups, such as a methyl group, an ethyl group, a propyl group, an isopropyl group, a butyl group, an isobutyl group, a tert-butyl group, a pentyl group, a neopentyl group, a hexyl group, a heptyl group, an octyl group, a nonyl group, a decyl group, and a dodecyl group; cycloalkyl groups, such as a cyclopentyl group, a cyclohexyl group, and a cycloheptyl group; aryl groups, such as a phenyl group, a tolyl group, a xylyl group, a naphthyl group, and abiphenylyl group; aralkyl groups, such as abenzyl group, aphenylethyl group, a phenylpropyl group, and a methylbenzyl group; and groups obtained from these groups by substituting a part or all of hydrogen atoms bonded to a carbon atom(s) therein with a cyano group, a halogen atom, such as fluorine, chlorine, and bromine, or the like. Examples of such substituted groups include a chloromethyl group, a 2-bromoethyl group, a 3-chloropropyl group, a 3,3,3-trifluoropropyl group, a chlorophenyl group, a fluorophenyl group, a cyanoethyl group, a 3,3,4,4,5,5,6,6,6-nonafluorohexyl group, etc. Typical examples of the monovalent hydrocarbon group include ones having 1 to 10 carbon atoms, and particularly typical examples thereof include ones having 1 to 6 carbon atoms. Preferable examples of the monovalent hydrocarbon group include unsubstituted or substituted alkyl groups having 1 to 3 carbon atoms, such as a methyl group, an ethyl group, a propyl group, a chloromethyl group, a bromoethyl group, a 3,3,3-trifluoropropyl group, and a cyanoethyl group; and unsubstituted or substituted phenyl groups, such as a phenyl group, a chlorophenyl group, and a fluorophenyl group. A methyl group and a phenyl group are particularly preferable.

d is preferably an integer of 5 to 2,000, particularly preferably an integer of 10 to 1,000, from the viewpoint of required viscosity.

Moreover, the viscosity at 25° C. is preferably 10 to 100,000 mPa·s, particularly preferably 100 to 10,000 mPa·s. When the viscosity is 10 mPa·s or more, the cured product of the resulting composition hardly exhibits oil bleeding. When the viscosity is 100,000 mPa·s or less, the resulting thermal conductive silicone composition has suitable flexibility.

When the component (F) is added to the inventive thermal conductive silicone composition, the addition amount is not particularly limited, could be 10 to 100 parts by mass relative to 100 parts by mass of the component (A). When the addition amount is in this range, this makes it easy to maintain the favorable flowability and operability of the thermal conductive silicone composition before curing, and to fill the composition with the component (C) thermally conductive filler.

In the inventive thermal conductive silicone composition, the dosage of the component (F) is preferably lower than 0.1 parts by mass, more preferably lower than 0.01 parts by mass, relative to 100 parts by mass of the component (A). In this way, it is possible to avoid oil leakage and contamination of the substrate of the thermally conductive silicone composition.

### Optional Component (G): Reaction Inhibitor

As a component (G), an addition reaction inhibitor is usable. As the addition reaction inhibitor, any of known addition reaction inhibitors used in usual addition reaction-curable silicone compositions can be employed. Examples thereof include acetylene compounds, such as 1-ethynyl-1-hexanol and 3-butyn-1-ol, various nitrogen compounds, organophosphorus compounds, oxime compounds, organochlorine compounds, etc. When the component (G) is blended, the use amount is preferably 0.01 to 1 parts by mass, more preferably 0.1 to 0.8 parts by mass, relative to 100 parts by mass of the component (A-1). With such a blend amount, the curing reaction proceeds sufficiently, and the molding efficiency is not impaired.

### Other Components

The inventive thermal conductive silicone composition may be further blended with other component(s), as necessary. Examples of the blendable optional components include heat resistance improvers, such as iron oxide and cerium oxide; viscosity adjusters, such as silica; colorants; release agents; etc.

### EMBODIMENTS

### Thermal Conductive Silicone Cured Product, and Production Method Therefor

A thermal conductive silicone cured product (thermally conductive molded product) according to the present invention is a cured product of the above-described thermal conductive silicone composition. The curing conditions of curing (molding) the thermal conductive silicone composition may be the same as those for known addition reaction-curable silicone rubber compositions. For example, the thermal conductive silicone composition is sufficiently cured at normal temperature, too, but may be heated as necessary. Preferably, the thermal conductive silicone composition is subjected to addition curing at 100 to 120° C. for 8 to 120 minutes. Such a cured product (molded product) of the present invention is excellent in thermal conduction.

### Thermal Conductivity of Molded Product

The inventive molded product has a thermal conductivity of preferably 3.1 W/m·K or more, which is a measurement value measured at 25° C. by hot disc method. The product having a thermal conductivity of 3.1 W/m·K or more is applicable to heat-generating members which generate large amounts of heat. Note that such a thermal conductivity can be adjusted by coordinating the type of the thermally conductive filler or combination of the particle sizes.

### Hardness of Molded Product

The inventive molded product is tested by a Zwick hardness tester. Note that such a hardness can be adjusted by changing the proportions of the component (A-1) and the component (B) to adjust the crosslinking density.

According to DIN53019, an Anton Paar MCR302 instrument was used to test the kinematic viscosity and static viscosity of the composition of the present invention.

Components (A) to (G) used in the following Examples and Comparative Examples are shown below.

### Component (A):

(A-1) an organopolysiloxane shown by the following formula (5), wherein X represents a vinyl group, and n represents the number resulting in the viscosity of 120 mPa·s.

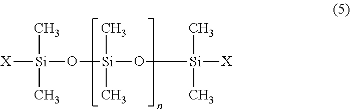

### Component (B):

(B-1) a side chain hydrogenpolysiloxane shown by the following formula (6), the hydrogen content is 1.7 mmol/g.

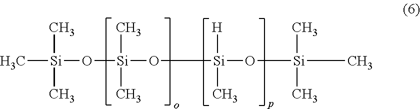

(B-2) a terminated hydrogenpolysiloxane shown by the following formula (5), wherein X represents hydrogen. The hydrogen content is 0.53 mmol/g.

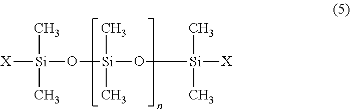

### Component (C):

(C-1) aluminum hydroxide with an average particle diameter of 1.5 μm
(C-2) aluminum hydroxide with an average particle diameter of 10 μm
(C-3) aluminum hydroxide with an average particle diameter of 90 μm

### Component (D):

a 2-ethyl hexanol solution of 5 wt % of chloroplatinic acid
Treatment agent Ea, di-ethyl di-oleyl titanate, which belongs to component (E-2)
Treatment agent Eb, isopropyl titanium triisostearate,
Treatment agent Ec, di-iso-butoxy titanium chelate (ethylacetoacetate titanate), CAS: 83877-91-2
Treatment agent Ed, hexadecyl-trimethoxy-silane
Treatment agents Eb, Ec or Ed do not belong to component (E-2).

### Component (G):

ethynyl methylidene carbinol as an addition reaction inhibitor.

The above-mentioned materials are provided by Wacker Chemie AG or purchased on market.

### Molding Method

After mixture, the compositions in Table 3 are obtained.

The obtained compositions in Table 3 were each poured into a mold with a size of 60 mm×60 mm×6 mm and molded using a press molding machine at 100° C. for 60 minutes.

### Evaluation Methods Thermal Conductivity:

The obtained compositions in Table 1 and Table 3 were each poured into a mold with a size of 60 mm×60 mm×6 mm and were used to measure the thermal conductivity.

Under conditions of 100° C. and 60 minutes, the compositions obtained in the following Examples and Comparative Examples in Table 3 were cured into sheet form with a thickness of 6 mm. Two sheets from each composition were used to measure the thermal conductivity with a thermal conductivity meter (product name: TC3000E, manufactured by Xi'an Xiatech Electronics Co., Ltd.).

Hardness: The compositions obtained in the following Examples and Comparative Examples were cured into sheet form with a thickness of 6 mm as described above. Two sheets from each composition were stacked on each other and measured by a Zwick hardness tester to get a Shore00 value.

### Density (Density):

The measurement was performed by Mettler Toledo ML204.

TABLE 1
Silicone grease composition

| | | C. Ex. | | C. Ex. | C. Ex. |
|---|---|---|---|---|---|
| | Ex. 1 | 2 | C. Ex. 3 | 4 | 5 |
| (A-1) | 1.67 | 1.67 | 1.67 | 1.67 | 1.67 |
| The | 15 | | | | |
| premix | | | | | |
| of (C) | | | | | |
| and Ea | | | | | |
| The | | 15 | | | |
| premix | | | | | |
| of (C) | | | | | |
| and Eb | | | | | |
| The | | | 15 | | |
| premix | | | | | |
| of (C) | | | | | |
| and Ec | | | | | |
| The | | | | 15 | |
| premix | | | | | |
| of (C) | | | | | |
| and Ed | | | | | |
| Ea | | | | | 0.06 |
| (C) | | | | | 14.94 |
| Total | 16.67 | 16.67 | 16.67 | 1.67 | 1.67 |
| Filling | 90.00 | 90.00 | 90.00 | 90.00 | 90.00 |
| rate | | | | | |
| [%] | | | | | |

Viscosity D = 10 1/s [mPa · s]

| | | | | | |
|---|---|---|---|---|---|
| Treated | 168700 | 136600 | 265900 | 162000 | 138200 |
| for | | | | | |
| 10 min | | | | | |
| Treated | 142100 | 150500 | 269000 | 186700 | 153700 |
| for | | | | | |
| 30 min | | | | | |
| Treated | 113300 | | | | 155700 |
| for | | | | | |
| 40 min | | | | | |
| Treated | 108800 | 154800 | Not | 188500 | 160200 |
| for | | | | | |
| 60 min | | | measurable | | |

The specific composition of “thermally conductive filler (C)” in Table 1 is shown in Table 2.

TABLE 2
thermally conductive filler (C)

| | Weight ratio |
|---|---|
| (C-1) | 2 |
| (C-2) | 2 |
| (C-3) | 6 |

In Ex.1, C.Ex.2, C.Ex.3 and C.Ex.4,
(a) place the thermally conductive filler (C) in the reaction kettle, and treat it with nitrogen for 10-15 min under the condition of stirring at 25° C.,
(b) heat the thermally conductive filler (C) to 120° C. within 5-10 mins,
(c) mix the thermally conductive filler (C) with the treatment agent Ea, Eb, Ec, Ed at a weight ratio of 249:1, and mix at 120° C. for 10 min, 30 min, 40 min, 60 min to obtain the premix of filler (C) and each treatment agent, that is the treated filler (CE),
(d) mix the premix with (A-1) again to obtain the thermally conductive silicone grease compositions of Ex.1, C.Ex.2, C.Ex.3 and C.Ex.4.

In the above steps, the speed of the high-speed mixer was 1400 RPM. This method belongs to the premix method.

In C.Ex.5, under the condition of 25° C., the treatment agent Ea is mixed with (A-1), and then the thermally conductive filler (C) is added to obtain the thermally conductive silicone grease composition of C.Ex.5. Wherein the weight ratio of the thermally conductive filler (C) to the treatment agent Ea is 249:1. This method belongs to the in-situ method.

In Table 1, using the premixes obtained after 40 minutes and 60 minutes, the viscosities of the thermally conductive silicone grease compositions prepared in Ex.1 are 113 300 mPa·s and 108 800 mPa·s respectively. The viscosities of these two products are significantly lower than the comparative examples using Eb, Ec, Ed treatments. In particular, a homogeneous premix could not be obtained in the case of prolonged mixing in C.Ex.3.

Even Ex.1 and C.Ex.5 use the same treatment agent Ea, after 30 minutes of treatment, the viscosity of the thermally conductive silicone grease composition in Ex.1 is significantly lower than that of C.Ex.5 using the in-situ method.

TABLE 2
Thermal conductive gap filler composition

| | Ex. 1-1 | C. Ex. 2-1 | C. Ex. 5-1 |
|---|---|---|---|
| (A-1) | 100.00 | 100.00 | 100 |
| (B-1) | 1.93 | 1.93 | 1.93 |
| (B-2) | 31.51 | 31.51 | 31.51 |
| Primix of (C) and Ea (treated for | 1144.7 | | |
| 60 min) | | | |
| Primix of (C) and Eb (treated for | | 1144.7 | |
| 60 min) | | | |
| (C) | | | 1140.12 |
| Ea | | | 4.58 |
| (D) | 0.64 | 0.64 | 0.64 |
| (G) | 0.32 | 0.32 | 0.32 |
| Filling rate | 0.89 | 0.89 | 0.89 |
| Viscosity D = 10 1/s (mPa · s) | 102 200 | 149 000 | 121 000 |
| Thermal conductivity (W/mK) | 3.21 | 3.14 | 3.28 |
| Hardness Shore 00 | 57 | 59 | 57.5 |
| Density (g/cm³) | 2.04 | 2.03 | 2.04 |

It can be seen from the comparison of Ex.1-1 and C.Ex.5-1 in Table 3 that even if the raw materials used in the two examples are exactly the same, the caulk product obtained in Ex.1-1 (using The premix of (C) and Ea (processing time 60 min) has a lower viscosity than the caulk product obtained from C.Ex.5-1 (using the in-situ method).

1-10. (canceled)

11. A treated filler (CE) obtained by mixing a component (C) thermally conductive filler with a component (E-2);
wherein the component (E-2) is a titanate compound represented by the following general formula (2) and/or an oligomer having a degree of polymerization of 2-5, 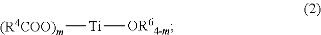
wherein R⁴ is a hydrocarbon group containing 6-30 carbon atoms, and contains at least one carbon-carbon unsaturated group;
wherein the number of carbon atoms is between 6-24, more preferably between 10-20, more preferably between 16-20;
wherein the component (E-2) contains 1-3 ethylenic bonds, preferably contains 1-2 ethylenic bonds, more preferably contains 1 ethylenic bond;
wherein R⁴COO— is preferably an oleic acid group;
wherein R⁶ is a hydrocarbon group containing 1-5 carbon atoms, preferably between 1-4 carbon atoms, more preferably methyl, ethyl, ethylene, allyl, propyl, isopropyl, butyl, isobutyl; more preferably propyl, isopropyl;
wherein m is 1 or 2, preferably m is 2; and
wherein the mixing conditions are 100-140° C., 32-70 min.

12. The treated filler (CE) of claim 11, wherein the mixing conditions are 100-140° C., 40-70 min; preferably 100-130° C., 30-65 min; more preferably 115-125° C., 35 −60 min; more preferably 118-122° C., 35 −60 min.

13. The treated filler (CE) of claim 11, wherein component (E-2) is one or more components selected from the group consisting of di-ethyl di-oleyl titanate, tri-ethyl oleyl titanate, di-n-propyl di-oleyl titanate, tri-n-propyl oleyl titanate, di-isopropyl di-oleyl titanate, tri-isopropyl oleyl titanate, di-butyl di-oleyl titanate, tri-butyl oleyl titanate, preferably di-isopropyl di-oleyl titanate, tri-isopropyl oleyl titanate, more preferably di-isopropyl di-oleyl titanate.

14. The treated filler (CE) of claim 11, wherein the component (C) thermally conductive filler comprises
10-25 wt % (C-1) aluminum hydroxide with an average particle diameter greater than or equal to 0.1 μm and less than or equal to 4 μm,
18-37 wt % (C-2) aluminum hydroxide with an average particle diameter of 4 μm or more and 20 μm or less,
48-65 wt % (C-3) aluminum hydroxide with an average particle diameter greater than or equal to 80 μm and less than or equal to 100 μm, and
wherein (C-1), (C-2) and (C-3), the component (C) in the composition is calculated as 100 wt %.

15. A method for treating a component (C) thermally conductive filler, comprising:
providing a component (C) thermally conductive filler and a component (E-2);
wherein the component (E-2) is a titanate compound represented by the following general formula (2) and/or an oligomer having a degree of polymerization of 2-5, 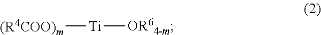
wherein R⁴ is a hydrocarbon group containing 6-30 carbon atoms, and contains at least one carbon-carbon unsaturated group;
wherein the number of carbon atoms is between 6-24, more preferably between 10-20, more preferably between 16-20;
wherein the component (E-2) contains 1-3 ethylenic bonds, preferably contains 1-2 ethylenic bonds, more preferably contains 1 ethylenic bond;
wherein R⁴COO— is preferably an oleic acid group;
wherein R⁶ is a hydrocarbon group containing 1-5 carbon atoms, preferably between 1-4 carbon atoms, more preferably methyl, ethyl, ethylene, allyl, propyl, isopropyl, butyl, isobutyl; more preferably propyl, isopropyl;
wherein m is 1 or 2, preferably m is 2; mixing the component (C) with the component (E-2); and
wherein the mixing conditions are 100-140° C., 32-70 min; preferably 100-140° C., 40-70 min; preferably 100-130° C., 30-65 min; more preferably 115-125° C., 35 −60 min; more preferably 118-122° C., 35 −60 min.

16. The method of claim 15, wherein under a condition of stirring, the component (C) thermally conductive filler is first subjected to nitrogen treatment, and then the component (E-2) is added.

17. The method of claim 16, wherein the nitrogen treatment time is greater than or equal to 5 minutes, preferably 5-60 minutes, more preferably 5-30 minutes, more preferably 5-15 minutes.

18. The method of claim 15, wherein the component (C) thermally conductive filler comprises
10-25 wt % (C-1) aluminum hydroxide with an average particle diameter greater than or equal to 0.1 μm and less than or equal to 4 μm,
18-37 wt % (C-2) aluminum hydroxide with an average particle diameter of 4 μm or more and 20 μm or less,
48-65 wt % (C-3) aluminum hydroxide with an average particle diameter greater than or equal to 80 μm and less than or equal to 100 μm, and
wherein (C-1), (C-2) and (C-3), the component (C) in the composition is calculated as 100 wt %.

19. A composition, comprising:
a component (A), that is an organopolysiloxane, preferably a component (A-1) that is an organopolysiloxane having two or more alkenyl groups per molecule;
an optional a component (B) that is an organohydrogenpolysiloxane having two or more hydrogen atoms directly bonded to silicon atoms and is contained in such an amount that the number of moles of hydrogen atoms directly bonded to silicon atoms in the component (B) is 0.1 to 5.0 times the number of moles of alkenyl groups derived from the component (A-1);
a treated filler (CE), wherein the treated filler (CE) comprises a component (C) thermally conductive filler and a component (E-2);
wherein the component (E-2) is a titanate compound represented by the following general formula (2) and/or an oligomer having a degree of polymerization of 2-5, 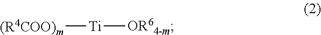
wherein R⁴ is a hydrocarbon group containing 6-30 carbon atoms, and contains at least one carbon-carbon unsaturated group;
wherein the number of carbon atoms is between 6-24, more preferably between 10-20, more preferably between 16-20;
wherein the component (E-2) contains 1-3 ethylenic bonds, preferably contains 1-2 ethylenic bonds, more preferably contains 1 ethylenic bond;
wherein R⁴COO— is preferably an oleic acid group;
wherein R⁶ is a hydrocarbon group containing 1-5 carbon atoms, preferably between 1-4 carbon atoms, more preferably methyl, ethyl, ethylene, allyl, propyl, isopropyl, butyl, isobutyl; more preferably propyl, isopropyl;
wherein m is 1 or 2, preferably m is 2;
wherein the filling amount of the treated filler (CE) is greater than or equal to 0.80, preferably greater than or equal to 0.84, preferably greater than or equal to 0.88, preferably greater than or equal to 0.89, preferably greater than or equal to 0.90; and
optional a component (D) that is a platinum group metal-based curing catalyst having a platinum group metal element content of 0.1 to 1,000 ppm relative to the component (A-1) based on mass.

20. The composition of claim 19, wherein the component (C) thermally conductive filler comprises
10-25 wt % (C-1) aluminum hydroxide with an average particle diameter greater than or equal to 0.1 μm and less than or equal to 4 μm,
18-37 wt % (C-2) aluminum hydroxide with an average particle diameter of 4 μm or more and 20 μm or less,
48-65 wt % (C-3) aluminum hydroxide with an average particle diameter greater than or equal to 80 μm and less than or equal to 100 μm, and
wherein (C-1), (C-2) and (C-3), the component (C) in the composition is calculated as 100 wt %.

21. The composition of claim 19, wherein the composition is used to form a thermally conductive member.

22. The composition of claim 21, wherein the thermally conductive member forms a part of a heat dissipation structure.

23. The composition of claim 22, wherein the heat dissipating structure comprises a heat dissipating component or a circuit board on which the heat dissipating component is mounted.
